(19) United States
(12) Patent Application Publication
(10) Pub. No.: US 2009/0133750 A1
(43) Pub. Date: May 28, 2009

(54) SOLAR CELL

(75) Inventors: Won Ha MOON, Suwon (KR); Chang Hwan Choi, Sungnam (KR); Ji Chul An, Goyang (KR); Chang Hwan Park, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/201,155

(22) Filed: Aug. 29, 2008

(30) Foreign Application Priority Data
Nov. 26, 2007 (KR) 10-2007-121039

(51) Int. Cl. H01L 31/00

(52) U.S. Cl. 136/256

(57) ABSTRACT

There is provided a solar cell including: a substrate; an energy absorption layer formed on the substrate and having a plurality of nanowire structures, each of the nanowire structures including an n-type semiconductor and a p-type semiconductor joined together; and n-type and p-type electrodes electrically connected to the n-type and p-type semiconductors, respectively. The solar cell exhibits high photoelectric efficiency due to pn junction of the nanowire structures. Further, the solar cell can absorb light falling within a substantially whole range of solar spectrum and does not require an epitaxial growth process, thereby overcoming drawbacks of an epitaxial layer such as crystal defect.

### CROSS-REFERENCE TO RELATED APPLICATIONS

This application claims the priority of Korean Patent Application No. 2007-121039 filed on Nov. 26, 2007, in the Korean Intellectual Property Office, the disclosure of which is incorporated herein by reference.

### BACKGROUND OF THE INVENTION

1. Field of the Invention

The present invention relates to a solar cell, more particularly, having an energy absorption layer of a nanowire structure.

2. Description of the Related Art

Recently, with rising interests in environmental issues and energy depletion, a growing attention has been drawn on a solar cell as an alternative energy since the solar cell is free from environmental pollution and high in energy efficiency.

The solar cell is broken down into a solar thermal cell generating steam necessary for rotating a turbine using solar heat and a solar photon cell converting photons from the sun into electrical energy using semiconductor characteristics. Notably, studies have been vigorously conducted on the solar photon cell (hereinafter, referred to as “solar cell”) in which electrons of a p-type semiconductor and holes of an n-type semiconductor generated by absorption of light are converted into electrical energy.

FIG. 1 is a schematic conceptual view for explaining operation of a conventional solar cell. Referring to FIG. 1, the solar cell 10 includes a junction structure of n-type and p-type semiconductor layers 11 and 12 and electrode pads 13a and 13b formed on the n-type and p-type semiconductor layers 11 and 12 formed thereon, respectively.

A bulb 14 as a light emitting part is connected to the electrode pads 13a and 13b of the solar cell 10. Then, when the solar cell 10 is exposed to a light source such as a solar light L, current flows across the n-type semiconductor layer 11 and the p-type semiconductor layer 12 due to a photovoltaic effect, thereby generating electromotive force. This process is construed to be reverse to a process of a light emitting device such as a light emitting diode (LED) in which electrons and holes are re-combined to emit light.

As described above, the bulb 14 electrically connected to the solar cell 10 can be turned on by the electromotive force generated due to the photovoltaic effect.

In the conventional solar cell 10, for example, in a case where a pn junction is formed by a silicon semiconductor, the silicon has a bandgap energy of 1.1 eV, which corresponds to an infrared ray region. When the solar cell receives light having a bandgap energy of 2 eV, which corresponds to a visible light region, in principle, the energy efficiency is about 50%.

Based on this photon energy efficiency, the single crystal solar cell made of silicon has a theoretical efficiency of maximum 45%, but a practical efficiency of 28% considering other losses.

Besides, a solar cell made of a single semiconductor material absorbs light of the partial wavelength, out of a wavelength ranging from 300 to 1800 nm, thereby not absorbing the solar light with efficiency.

This accordingly has led to a need in the art for manufacturing a solar cell with higher efficiency.

### SUMMARY OF THE INVENTION

An aspect of the present invention provides a solar cell having an energy absorption layer of a nanowire structure, thereby ensuring high photoelectric conversion efficiency.

According to an aspect of the present invention, there is provided a solar cell including: a substrate; an energy absorption layer formed on the substrate and having a plurality of nanowire structures, each of the nanowire structures including an n-type semiconductor and a p-type semiconductor joined together; and n-type and p-type electrodes electrically connected to the n-type and p-type semiconductors, respectively.

The nanowire structures may be arranged randomly in the energy absorption layer. The nanowire structure may have a length that is at least 1.5 times greater than a thickness of the energy absorption layer.

The solar cell may further include a transparent electrode layer formed on the energy absorption layer.

The substrate may be formed of a material reflecting solar light.

The nanowire structure may have a diameter of 5 to 500 nm.

The energy absorption layer may include at least two types of nanowire structures formed of different materials from each other capable of absorbing light of different wavelength bands.

The at least two types of nanowire structures may be formed in different areas of the energy absorption layer, respectively.

The energy absorption layer may include a plurality of layers, wherein the plurality of layers are formed of different materials from one another to absorb light of different wavelength bands, and adjacent ones of the plurality of layers are connected to each other by a tunneling layer.

The energy absorption layer may be formed by applying a mixture of the nanowire structure having the n-type and p-type semiconductors joined together and an organic binder, and degreasing the organic binder.

The nanowire structure may be added in the mixture at 70 to 95 volumes with respect to a total volume of the mixture.

According to another aspect of the present invention, there is provided a solar cell including: a substrate; an n-type semiconductor layer formed on the substrate; an energy absorption layer formed on the n-type semiconductor layer, the energy absorption layer including a plurality of nanowires each formed of a p-type semiconductor; and n-type and p-type electrodes electrically connected to the n-type semiconductor and the energy absorption layer, respectively.

According to still another aspect of the present invention, there is provided a solar cell including: a substrate; an energy absorption layer formed on the substrate, the energy absorption layer including a plurality of nanowire structures each formed of an n-type semiconductor; a p-type semiconductor layer formed on the energy absorption layer; and n-type and p-type electrodes electrically connected to the energy absorption layer and the p-type semiconductor, respectively.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic conceptual view illustrating operation of a conventional solar cell;

FIG. 2 is a cross-sectional view illustrating a solar cell according to an exemplary embodiment of the invention;

FIG. 3 is a cross-sectional view illustrating a solar cell according to another exemplary embodiment of the invention;

FIG. 4 is a perspective view illustrating an example of a nanowire structure described with reference to FIGS. 2 and 3;

FIGS. 5A and 5B are top views illustrating arrangement of nanowire structures of an energy absorption layer according to an exemplary embodiment of the invention;

FIGS. 6A and 6B are procedural cross-sectional view illustrating a method of manufacturing a nanowire structure shown in FIG. 4; and

FIG. 7 is a cross-sectional view illustrating a solar cell according to still another exemplary embodiment of the invention.

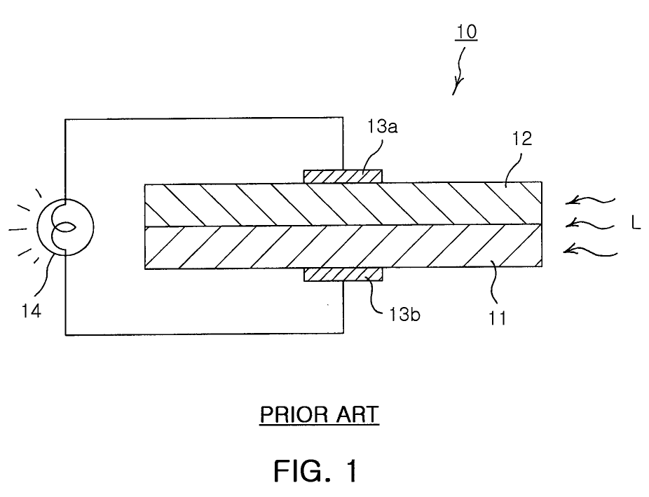

### DETAILED DESCRIPTION OF THE PREFERRED EMBODIMENT

Exemplary embodiments of the present invention will now be described in detail with reference to the accompanying drawings. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference signs are used to designate the same or similar components throughout.

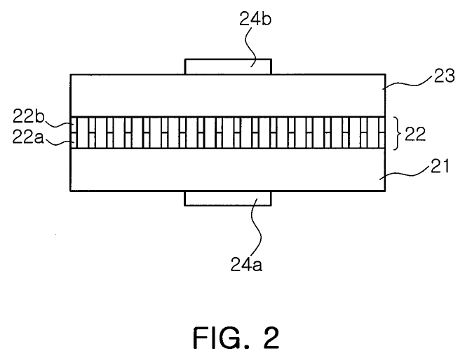

FIG. 2 is a cross-sectional view illustrating a solar cell according to an exemplary embodiment of the invention.

Referring to FIG. 2, the solar cell 20 of the present embodiment includes a substrate 21, an energy absorption layer 22, a transparent electrode layer 23, n-type and p-type electrodes 24a and 24b.

The energy absorption layer 22 is formed of a plurality of nanowire structures 22a and 22b and receives a solar light to generate an electromotive force.

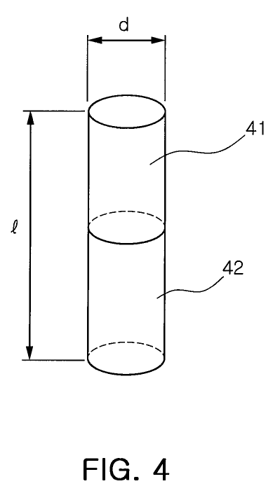

Each of the nanowire structures 22a and 22b has an n-type semiconductor 22a and a p-type semiconductor 22b joined together, and is shaped as a nano-sized rod as shown in FIG. 4. In a case where light is provided, holes h⁺ and electrons e⁻ are generated from an interface between the n-type and p-type semiconductors 22a and 22b. Thus, the holes migrate to the p-type semiconductor 22b and the electrons migrate to the n-type semiconductor 22a to thereby generate an electromotive force. An electric energy generated as such can be collected by a capacitor (not shown) connected to the n-type and p-type electrodes 24a and 24b.

Meanwhile, when it comes to a ‘nanowire’ used in the specification, first, a ‘nanorod’ denotes a material shaped as a rod having a diameter ranging from several nm to tens of nm. Here, the nanorod elongated into a wire shape is referred to as a ‘nanowire’.

As in the present embodiment, the energy absorption layer as a light receiving area is formed of a plurality of nanowire structures. This ensures quantum effect and increases an overall light receiving area, accordingly leading to significant increase in light receiving efficiency. In the present embodiment, the light receiving area features nanowire structures but may adopt a nanorod with a smaller length than the nanowire.

As described, in the present embodiment, the energy absorption layer 22 formed of the nanowire structures 22a and 22b can assure high photoelectric conversion efficiency. Moreover, the energy absorption layer 22 is not a semiconductor single crystal formed on the substrate by thin film growth, thus resulting in very few crystal defects and accordingly higher photoelectric conversion efficiency.

The plurality of nanowire structures 22a and 22b may have voids therebetween filled with air, or a transparent material to prevent decline in light absorption.

The substrate 21 may reflect solar light to be directed to the energy absorption layer 22, and be made of a transparent material.

In the same manner, in the present embodiment, the energy absorption layer 22 has the transparent electrode layer 23 formed thereon. However, the transparent electrode layer 23 may be substituted by a solar light reflective layer. In this case, the substrate 21 may be formed of a transparent electrode layer. That is, in the present embodiment, the substrate 21 and the transparent electrode layer 23 enclosing the energy absorption layer 22 of a nanowire structure may be changed in position from each other considering an incident direction of the solar light. Alternatively, the energy absorption layer 22 may be enclosed by both transparent electrode layers or both reflective layers in place of the substrate 21 and the transparent electrode layer.

However, the transparent electrode layer 23 of the present embodiment is not an essential element and may not be formed.

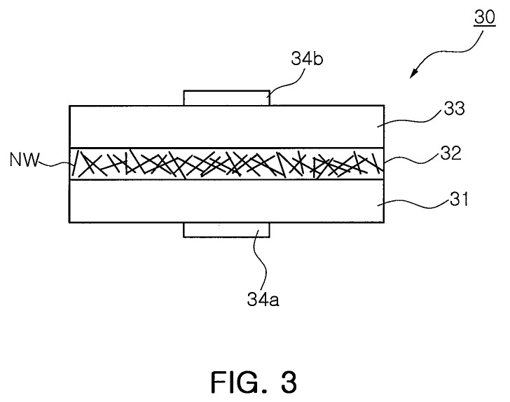

FIG. 3 is a cross-sectional view illustrating a solar cell according to another exemplary embodiment of the invention.

In the same manner as FIG. 2, the solar cell 30 includes a substrate 31, an energy absorption layer 32, a transparent electrode layer 33, n-type and p-type electrodes 34a and 34b.

In the present embodiment, compared to the previous embodiment of FIG. 2, nanowire structures of the energy absorption layer are arranged in a different fashion. Meanwhile, other components are construed to be identical to those of FIG. 2, and thus will not be explained in further detail.

The nanowire structures NW of the energy absorption layer 32 of the present embodiment are arranged randomly.

To form the nanowire structures NW with this random arrangement, a mixture having the nanowire structures and an organic binder mixed therein is applied, and then the organic binder is degreased from the mixture by heating or/and compression.

Here, a dispersant may be utilized to ensure the nanowire structures NW to be dispersed uniformly in the organic binder. Degreasing of the organic binder leaves only the nanowire structures NW as a layer. Therefore, the nanowire structures NW may be added at a 70 to 95 volumes of the mixture. The nanowire structures NW added at less than 70 volumes are structurally unstable due to high porosity after degreasing. Meanwhile, the nanowire structures N/W may not exceed 95 volume % to ensure a sufficient amount of the organic binder.

Also, unlike FIG. 2, even though the nanowire structures NW of pn junction are not arranged in a predetermined orientation, a great number of nanowire structures NW remain electrically connected to one another, thus not preventing current from flowing.

However, to ensure more active electrical connection of the nanowire structures NW, each of the nanowire structures NW may have a predetermined length or more.

That is, the nanowire structure NW having a length greater than a thickness of the energy absorption layer 32 can be sufficiently connected to the substrate and the transparent electrode layers 31 and 33. Accordingly, in the present embodiment, the nanowire structure NW has a length that is at least 1.5 times greater than the energy absorption layer 32.

FIG. 4 is a perspective view illustrating an example of the nanowire structure described with reference to FIGS. 2 and 3.

Referring to FIG. 4, as a representative example, the nanowire structure applicable to the present embodiment has an n-type semiconductor 41 and a p-type semiconductor 42 joined together.

Here, a material for the nanowire structure can be appropriately selected in view of a wavelength band of absorbable solar light. Specifically, the material for the nanowire structure may adopt AlGaInP(2.1 eV), InGaP(1.9 eV), AlGaInAs(1.6 eV), InGaAs(1 eV), and Ge(0.7 eV). Here, parentheses denote an approximate energy value of the absorbable solar light.

The nanowire structure may have a diameter d of 5 to 500 nm. As described above, particularly, when configured as in FIG. 3, the nanowire structure has a length l that is at least 1.5 times greater than the energy absorption layer 32.

Meanwhile, the nanowire structure of the present embodiment features a pn junction structure but is not limited thereto.

That is, even though not shown, the nanowire structure may be formed of only one of the n-type semiconductor and the p-type semiconductor. Here, another conductive semiconductor material layer with the other one of the n-type and the p-type may be formed adjacent to the nanowire structure to constitute the energy absorption layer.

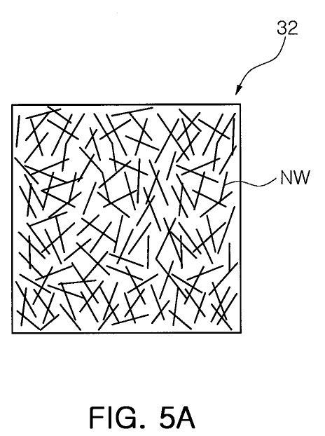

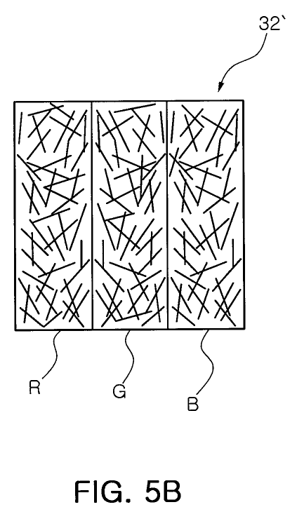

FIGS. 5A and 5B are top views illustrating arrangement of the nanowire structures of the energy absorption layer applicable to an exemplary embodiment of the invention, respectively.

First, the energy absorption layer of FIG. 5A is identical in arrangement to the energy absorption layer 32 shown in FIG. 3.

Particularly, the nanowire structures NW are formed of different materials from one another to absorb solar light of various wavelength bands. The nanowire structures NW are arranged randomly in the energy absorption layer 32, accordingly capable of absorbing solar light of a wide wavelength band. Also, the energy absorption layer 32 can absorb a substantially whole range of wavelength bands of the solar light without being formed of a multilayer structure.

Meanwhile, FIG. 5B is a modified example of FIG. 5A, in which nanowire structures NW are arranged into three areas in an energy absorption layer 32′.

More specifically, the nanowire structures NW are made of three different types of materials capable of emitting light of red color (R), green color (G) and blue color (G), respectively. Accordingly, unlike FIG. 5A, the nanowire structures NW made of different types of materials are formed in different areas from one another.

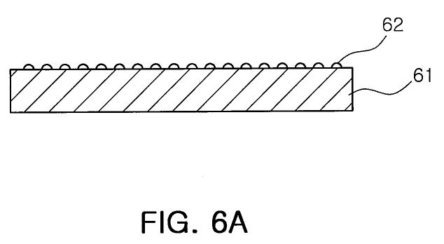

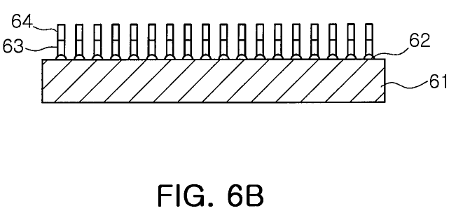

FIGS. 6A and 6B are schematic cross-sectional views illustrating a method of manufacturing a nanowire structure shown in FIG. 4.

First, as shown in FIG. 6A, a nano-sized catalyst metal pattern 62 is formed on a substrate 61. Here, the catalyst metal pattern 62 is made of a transition metal such as nickel and chrome. To form the catalyst metal pattern 62, the transition metal is applied on the substrate 61, and heated and condensed into a nano-size.

Thereafter, as shown in FIG. 6B, nanowire structures formed of a semiconductor material are grown on the catalyst metal pattern 62 by deposition. The semiconductor formed on the catalyst metal pattern 62 can be grown as nanowires 63 and 64 each having a diameter equal to a size of the catalyst metal pattern 62. Here, to form the pn junction structure, the n-type semiconductor 63 and the p-type semiconductor 64 are doped to a different concentration from each other.

However, the nanowire, which is obtained by a catalyst-based process as described above, may be formed by other known methods, for example, by utilizing anode aluminum (AAO) as a template.

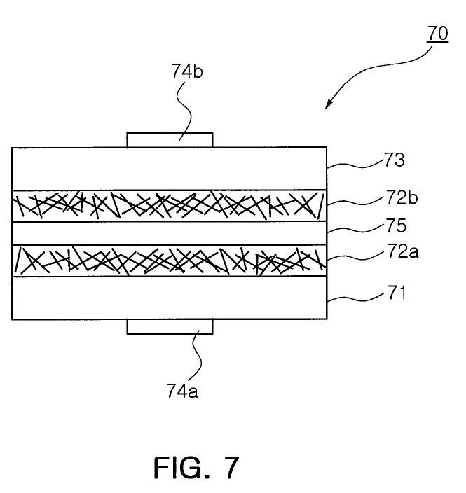

FIG. 7 is a cross-sectional view illustrating a solar cell according to still another exemplary embodiment of the invention.

The solar cell 70 of the present embodiment includes a substrate 71, energy absorption layers 72a and 72b, a transparent electrode layer 73, n-type and p-type electrodes 74a and 74b in the same manner as the solar cells described above.

In the present embodiment, the energy absorption layer of FIG. 2 is expanded into a two-layer structure and other constituents are construed to be identical to those of FIG. 2, and thus will not be described in further detail.

As shown in FIG. 7, unlike the solar cells of the previous embodiments described above, the solar cell 70 includes first and second energy absorption layers 72a and 72b and a tunneling layer 75 formed between to enable carriers to be tunneled therethrough. In the present embodiment, the energy absorption layer of a multi-layer structure is employed to increase light absorption and further expand a wavelength range of absorbable light.

Of course, here, the material for the energy absorption layer and the tunneling layer and the number of materials may be varied appropriately.

As set forth above, according to exemplary embodiments of the invention, a solar cell has an energy absorption layer formed of nanowire structures to ensure high photoelectric conversion efficiency.

In addition, the solar cell can absorb light falling within a substantially whole range of the solar spectrum and does not requires an epitaxial growth process, thereby not entailing drawbacks of an epitaxial layer such as crystal defects.

While the present invention has been shown and described in connection with the exemplary embodiments, it will be apparent to those skilled in the art that modifications and variations can be made without departing from the spirit and scope of the invention as defined by the appended claims.

What is claimed is:

1. A solar cell comprising:
a substrate;
an energy absorption layer formed on the substrate and having a plurality of nanowire structures, each of the nanowire structures comprising an n-type semiconductor and a p-type semiconductor joined together; and
n-type and p-type electrodes electrically connected to the n-type and p-type semiconductors, respectively.

2. The solar cell of claim 1, wherein the nanowire structures are arranged randomly in the energy absorption layer.

3. The solar cell of claim 1, wherein the nanowire structure has a length that is at least 1.5 times greater than a thickness of the energy absorption layer.

4. The solar cell of claim 1, further comprising a transparent electrode layer formed on the energy absorption layer.

5. The solar cell of claim 1, wherein the substrate is formed of a material reflecting solar light.

6. The solar cell of claim 1, wherein the nanowire structure has a diameter of 5 to 500 nm.

7. The solar cell of claim 1, wherein the energy absorption layer comprises at least two types of nanowire structures formed of different materials from each other capable of absorbing light of different wavelength bands.

8. The solar cell of claim 7, wherein the at least two types of nanowire structures are formed in different areas of the energy absorption layer, respectively.

9. The solar cell of claim 7, wherein the energy absorption layer comprises a plurality of layers, wherein the plurality of layers are formed of different materials from one another to absorb light of different wavelength bands, and adjacent ones of the plurality of layers are connected to each other by a tunneling layer.

10. The solar cell of claim 1, wherein the energy absorption layer is formed by applying a mixture of the nanowire structure having the n-type and p-type semiconductors joined together and an organic binder, and degreasing the organic binder.

11. The solar cell of claim 10, wherein the nanowire structure is added in the mixture at 70 to 95 volume % with respect to a total volume of the mixture.

12. A solar cell comprising:
a substrate;
an n-type semiconductor layer formed on the substrate;
an energy absorption layer formed on the n-type semiconductor layer, the energy absorption layer comprising a plurality of nanowires each formed of a p-type semiconductor; and
n-type and p-type electrodes electrically connected to the n-type semiconductor and the energy absorption layer, respectively.

13. A solar cell comprising:
a substrate;
an energy absorption layer formed on the substrate, the energy absorption layer comprising a plurality of nanowire structures each formed of an n-type semiconductor;
a p-type semiconductor layer formed on the energy absorption layer; and
n-type and p-type electrodes electrically connected to the energy absorption layer and the p-type semiconductor, respectively.
